(19) United States
(12) Patent Application Publication
(10) Pub. No.: US 2018/0105935 A1
(43) Pub. Date: Apr. 19, 2018

(54) LOADING WORKPIECES IN A COATING SYSTEM

(71) Applicant: CemeCon AG, Würselen (DE)

(72) Inventors: Werner Kölker, Herzogenrath (DE); Walter May, Aachen (DE)

(73) Assignee: CemeCon AG, Würselen (DE)

(21) Appl. No.: 15/562,854

(22) PCT Filed: Apr. 1, 2016
(86) PCT No.: PCT/EP2016/057279

§ 371 Date: Sep. 28, 2017

(30) Foreign Application Priority Data
Apr. 2, 2015 (DE) 10 2015 105 169.9

(51) Int. Cl. C23C 16/458; C23C 14/50; B05B 13/02; C23C 16/50

(52) U.S. Cl. CPC C23C 16/4583; C23C 16/50; B05B 13/0242; C23C 14/50

(57) ABSTRACT

The invention relates to a loading device for workpieces (16) in a coating system (10) and a method for loading the workpieces (16). An upright stand (22) has a number of openings (24) arranged above one another in an outward-facing surface (44). A number of insertion sleeves (30) are provided for accommodation in the openings (24), with the insertion sleeves (30) each having a shaft (32) and a retaining structure (24) as well as a borehole (26) to accommodate a workpiece (16). The openings (24) and the shafts (32) of the insertion sleeves (30) are designed such that the insertion sleeves (30) are insertable through the openings (24). The openings (24) and the retaining structures (34) are designed such that holding engagement occurs between the insertion sleeves (30) and the openings (24).

The invention relates to the loading workpieces in a coating system, in particular a loading device for this, a coating system equipped with such a device and a method for loading the workpieces.

Various types of coating systems are known for the application of surface coatings to workpieces, particularly to tools. For example, coating materials are deposited on workpieces in physical vapor deposition (PVD) or chemical vapor deposition (CVD) coating systems.

Inside the coating system—i.e. in the vacuum chamber of a vacuum coating system, for example—the workpieces are arranged and positioned so that they are exposed to the coating process. The function of a loading device is to hold the workpieces properly, position and usually also to move them inside the coating chamber so that the workpieces are exposed to the coating process in the most advantageous way possible, in particular to facilitate a coating which is as uniform as possible.

Turntables are known for arranging the workpieces, particularly ones on which in turn orbitally rotating plates with workpiece mounts are situated.

In industrial coating, a number of workpieces are loaded in each case, i.e. arranged on the loading device, and then the coating procedure is carried out. The coated tools are removed afterward. Thus simple handling is advantageous where it enables placement and removal of the workpieces in a particularly easy manner. However, at the same time, the workpieces should be held in a defined position as much as possible during the coating. Insofar as substrate biasing is used in the coating procedure, electrical contact is also required for workpieces.

One type of tools for which coating is advantageous, particularly with layers to protect against wear, is cylindrical workpieces or those which at least have a cylindrical shaft, particularly tools such as rotating tools like drill bits, milling cutters, etc.

US 2008/0305267 A1 discloses a device and a method for coating a number of substrates. A rotatable support is arranged in a vacuum chamber with sputter targets. Pallets are arranged on the support inside the vacuum chamber, each having discs arranged one above the other on an axis. Each disc includes a plurality of boreholes along the periphery with a cylindrical boundary.

A plurality of spindles with cylindrical walls are designed to be borne in the boreholes, and the wall of the spindle can be knurled. During the coating procedure, the discs and support are rotated about their respective axes, so the spindles in the boreholes are subject to two centripetal forces, causing the spindles to roll in the holes.

DE 39 33 911 A1 discloses a substrate holder to use for coatings of geometrically complex substrate bodies under vacuum, where the substrates are to execute a spin. An orbiting element of an epicyclic system has two parallel shafts on which concentric rings are mounted which have boreholes of the same pitch. Substrate holders with substrates to be coated—such as spiral drill bits—are set in the boreholes. When the shafts are rotated, the rings with the boreholes move; the substrate holders are supported on the walls of the boreholes so that they perform a rolling motion on the wall of the borehole and thus spin.

DE 697 09 306 T2 discloses a modular support for concurrent coating of numerous workpieces. Two support plates spaced apart from one another are welded onto a central shaft; these have a number of bushings formed by hollow, cylindrical sleeve elements. Spindle assemblies with a shaft section are accommodated in the bushings and have retaining devices with a cup-shaped element for accommodating a plurality of workpieces to be coated such as scoops or blades. The holder is rotated on its longitudinal axis by a drive system during the coating process so that each workpiece is turned by the force of gravity and friction between the bushings and spindle assemblies.

DE 20 2004 009 256 U1 describes a support device for workpieces to hold workpieces, particularly during surface treatment such as coating, for example. The support device for workpieces comprises a substrate table with an orbiting element which can be rotated about an epicyclic axis. An orbiting element has boreholes in which sleeve-shaped satellite elements are rotatably mounted.

DE 10 2013 007 452 A1 discloses a holder for drill bits in a vacuum coating system. These are fixated on a receiving sleeve by pins which engage in clamping slots of the drill bit.

It is the object of the invention to propose a loading device, a coating system equipped with such a device and a method for loading workpieces in a coating system in which flexible loading with particular ease is possible with different workpieces.

The object is solved by a loading device according to claim 1, a coating system according to claim 13 and a method according to claim 15. Dependent claims refer to advantageous embodiments of the invention.

The inventive loading device comprises at least one stand arranged upright. The stand has an outer surface, i.e. a front facing outward. The outer surface can point in the direction of a chamber wall, preferably in the direction of a source of coating material such as a magnetron cathode.

A number of openings arranged one over another is provided in the preferably at least essentially vertically oriented (i.e. ±15°, for example) outer surface corresponding to the upright position of the stand. A number of insertion sleeves are provided for accommodation in the openings. The insertion sleeves each have a shaft and a retaining structure as well as a borehole for accommodating a workpiece. Here the borehole is preferably used to insert a cylindrical workpiece or respectively a cylindrical shaft of a workpiece. The borehole need not be round, but this is preferred. Furthermore, the borehole is preferably cylindrical. A shaft of a workpiece is particularly preferred which fits in the borehole but is accommodated without an undercut, so that it can simply be inserted and then removed again the same way.

The stand is situated upright, i.e. either completely vertical or possibly also slightly inclined with respect to the vertical and can be placed on a rotating device such as a rotating plate so that it is moved during the coating process. Here an axis of rotation is preferably arranged vertically and thus at least essentially parallel to the holders and their outer surfaces.

The shaft of the insertion sleeves is intended to extend through the respective opening into the stand. For this the associated opening is adapted in its size and dimensions to the size of the insertion sleeve to be inserted there such that the shaft of the insertion sleeve can be inserted through and the retaining structure of the insertion sleeve can engage in a holding manner with the opening.

The retaining structure of an insertion sleeve and the associated opening are constructed in shape and dimensions relative to each other such that after insertion of the shaft a holding engagement results between an opening and an insertion sleeve inserted in it.

It is preferred that the insertion sleeves can be fixed in place so that they are fixated in the openings for operation of the coating system. The position of the insertion sleeves us then preferably fixed and thus immovable with respect to the holder. A sufficiently uniform coating can be achieved by rotating the holder, for example on a rotating plate.

Due to the possibility of accommodating workpieces in the borehole, a loading device designed according to the invention is particularly well suited to hold said workpieces during the coating.

The borehole preferably has a shape and dimensions suitable for the workpiece or respectively for the shaft of the workpiece. Also, with the preferred use of stands and insertion sleeves made of metal, good electrical contacting can be ensured.

Here the stand of the loading device can be constructed in a particularly simple and cost-effective manner, as a sheet metal part for example, i.e. from flat material which is bent in the desired shape, for example, and in which the openings are formed by die cutting or laser cutting, for example. The openings can be formed in the sheet metal material so the retaining structures can engage with the edges or borders of the openings.

At least a plurality of the openings, preferably all openings, can have the same shape and dimensions. On the other hand, various types of insertion sleeves can be used, preferably with the same external shape but with different boreholes adapted in each case to the requirements of the workpieces. Thus the insertion sleeves form a kind of adapter for accommodating various workpieces on the stand. This enables equipping in a particularly flexible manner and makes quick adaptation of the loading device for different batches easily possible.

Insertion sleeves with boreholes of different diameters can be provided. Here the boreholes are preferably not all the way through but instead have a limited drill depth. Different insertion sleeves with various drill depths can be used depending on the length of the workpieces.

The insertion sleeves can be constructed in a particularly simple manner and thus cost-effectively as well. A cylindrical form of at least the insertion sleeve shafts is preferred. While presently a cylindrical form is generally understood as an elongated form of uniform cross section, which includes, for example, the insertion sleeves of polygonal shapes, etc., a circular cylindrical form of the insertion sleeve shafts is preferred, because this shape is especially suited for simple, cost-effective manufacture as well as easy handling. Generally, a shape which is at least essentially rotationally symmetric is preferred for the insertion sleeves, which makes fabricating it as a turned part particularly simple and cost-effective.

Thus it is possible to manufacture the parts of the loading device simply and cost-effectively. In particular the preferred combination of the stand as a sheet metal part and the insertion sleeves as turned parts enables simple, cost-effective fabrication.

According to a further embodiment of the invention, the insertion sleeve retaining structures are designed to include a stop portion which cannot be inserted all the way through the openings. The retaining structures can preferably be situated on an end of the sleeves in each case. The stop portion can particularly be a flange of greater diameter which does not pass through the opening. It is further preferred that the retaining structures have recesses on the insertion sleeve circumference to engage with the edges of the openings, for example as at least partially circumferential grooves, with fully circumferential ones particularly preferred.

According to a further embodiment of the invention, the openings are designed to have a first, wider portion and a second, narrower portion. The first portion can be used for inserting the shafts of the insertion sleeves, while the insertion sleeve retaining structures then engage with the edge of the second portion. The first, wider portion is preferably situated above the second, narrower portion so the insertion sleeve is acted upon by the force of gravity in the direction of the second, narrower portion. The two portions can, for example, be designed as round boreholes with different diameters.

A further embodiment of the invention envisages that the openings and retaining structures are designed so that the insertion sleeves are able to be tilted at a working angle with respect to the stand. This is understood to mean that the insertion sleeves are first of all not fixed, at least in the engagement position with respect to their angle relative to the holder. The working angle here can, for example, be formed between the longitudinal center line of the insertion sleeve and the direction perpendicular to the opening. Preferably the openings and the retaining structures can be designed so that the insertion sleeves are able to be guided through the openings in an insertion position perpendicular to the outer surface of the stand and the insertion sleeves in the inserted state can be tilted by a working angle with respect to the preferably horizontal insertion position.

Preferably the insertion sleeves and the holder with the openings are arranged so the insertion sleeves are accommodated in the engagement position at the holder in such a way that the boreholes point at least a small amount obliquely upward. Then accommodation and good holding of the workpieces is possible by simple insertion in the boreholes while due to the oblique arrangement the force of gravity ensures that the workpieces cannot fall out of the boreholes.

The arrangement is preferably such that the holder is arranged at least vertically in essence and the insertion sleeves in engagement with it form an angle of 3 to 60 degrees with the horizontal, for example, preferably less than 45 degrees, and with particular preference 5 to 30 degrees with the horizontal. This position of the insertion sleeves can be set by their shafts tilting the insertion sleeves obliquely downward due to their weight and dimensions until these are held in the desired position by the engagement between the retaining structures and the openings with boreholes pointing obliquely upward. Preferably the insertion sleeves can be locked on the holder after setting in a suitable position, for example by a locking strip, particularly with a comb-like structure.

According to a further embodiment of the invention, the openings formed on the stand are at least partially staggered and/or skewed with respect to one another. In particular, openings situated directly over one another can in each case have an offset or twist with respect to one another. This can result in the insertion sleeves therein not being arranged in parallel but rather in directions which deviate from one another. Such an arrangement can be advantageous for uniform coating. Correspondingly, it is preferred that an arrangement of openings above one another on the stand is formed such that with the existing engagement with the insertion sleeves accommodated therein these are arranged with at least two different angles with respect to the stand.

While such a staggered arrangement can be achieved, for example by correspondingly curved shapes of the holder, it is preferred that the openings are arranged in a skewed manner with respect to one another. In this case, the openings do not have a round shape, but rather have, for example as explained above, a first, wider portion and a second, narrower portion. For example, openings arranged one above another can then be skewed by a particular amount with respect to one another, for example 5 to 45 degrees, so insertion sleeves accommodated at an angle therein can form correspondingly different angles with respect to the holder.

A number of stands arranged next to each other is preferred. While various stands can be orbitally rotatable with respect to one another, the inventive arrangement is particularly suited for external loading in which holders are arranged upright and adjacent to one another around the circumference with the workpieces accommodated in the insertion sleeves extending outward from said holders in each case.

The invention also refers to a coating system with a loading device as described above. The coating system comprises a coating chamber, i.e. an enclosed space, in which the coating can be applied. The holder(s) are arranged inside the coating chamber. The coating is applied to the workpieces held in the loading device with coating agent. The coating chamber is particularly preferred designed as a vacuum chamber, and the coating agents function to produce a plasma from which constituents are deposited on the workpieces as a coating.

In the inventive method for loading workpieces in a coating system, workpieces are inserted in the boreholes of the insertion sleeves described above and the insertion sleeves are inserted in the openings of the stand. The sequence of these steps is insignificant; it is possible to place the workpieces first in the insertion sleeves and insert the insertion sleeves in the openings afterward as well as to apply the reverse sequence.

An embodiment of the invention is described below in more detail based on drawings. These show in:

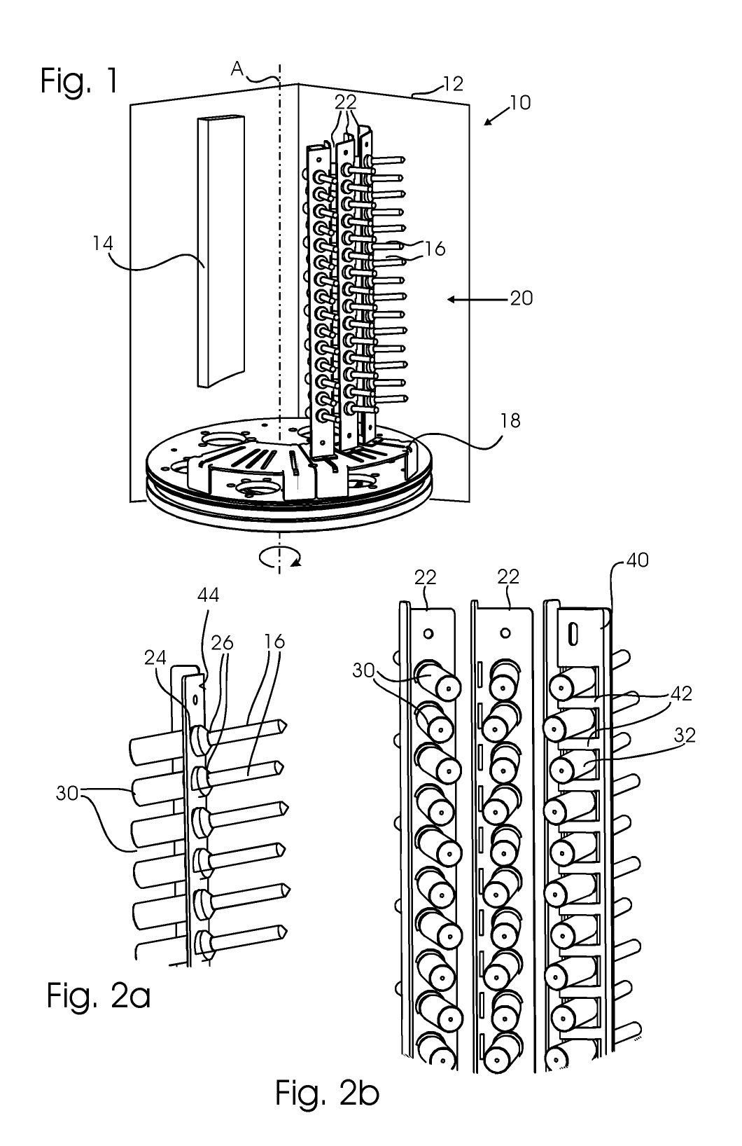

FIG. 1 a perspective, partially schematic view of a coating system with a loading device;

FIGS. 2a, 2b perspective views of parts of the loading device from FIG. 1;

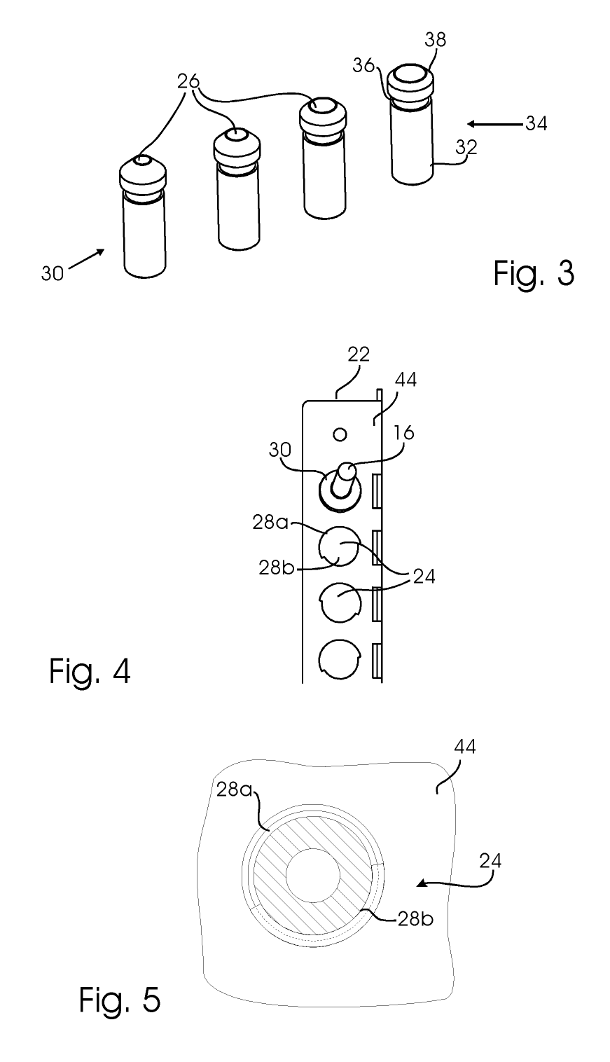

FIG. 3 various insertion sleeves for the loading device from FIG. 1 in a perspective view;

FIG. 4 part of the loading device in a top view;

FIG. 5 a representation of the part from FIG. 4 in cross section;

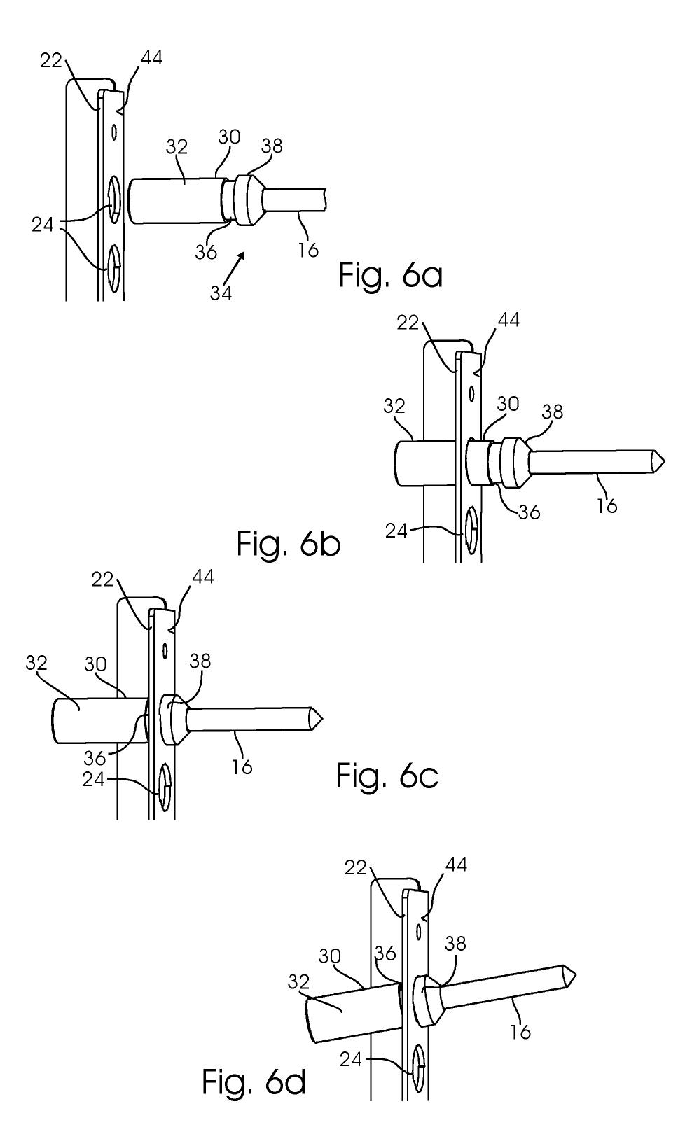

FIGS. 6a-6d a representation of the part of the loading device from FIG. 4, FIG. 5 in a side view for various positions.

FIG. 1 shows a coating system 10 in a partially schematic view. For example, it can be a PVD coating system with a vacuum chamber 12 in which multiple magnetron cathodes 14 are situated (of which only one is shown as an example in FIG. 1) with which a plasma can be produced in the interior of the vacuum chamber 12, the constituents of which are deposited to form a surface coating on workpieces 16.

The workpieces 16 are arranged inside the chamber 12 on a loading device 20. This is positioned on a rotating plate 18 which can turn around a vertical axis of rotation A, and comprises a number of standing vertical holders 22 which are situated next to one another. Whereas for the sake of clarity only three holders 22 are shown situated next to one another in FIG. 1, the loading device 20 comprises a greater number of such holders 22, for example 18, which are arranged next to one another altogether in the shape of the circle on the rotating plate 18. Here the loading device 20 provides external loading in which the workpieces 16 are arranged in a stationary manner on the holder 22 facing outward in each case.

As seen in FIG. 4, for example, each of the holders 22 is a sheet metal bent part made of sheet metal bent at an angle. A number of openings 24 are cut out above one another in a flat, upright, outward-facing surface 44 of each holder 22.

As shown in FIG. 2a, 2b for example, insertion sleeves 30 are inserted in the openings 24 when the holder 22 is equipped. The insertion sleeves 30 have a borehole 26 in the center in each case. The workpieces 16 are inserted into the boreholes 26. Here the boreholes 26 each have a limited drill depth so the workpieces 16 can only be inserted up to the drill depth and thus assume a defined position.

The workpieces 16 in the example shown are pin-shaped, cylindrical parts such as drill bits, router bits, etc. However, workpieces of other shapes which have a cylindrical shaft can also be inserted in the boreholes 26.

As shown in FIG. 3, various types of insertion sleeves 30 are used to accommodate workpieces 16 with different shaft diameters, said sleeves having identical external dimensions but boreholes 26 of differing diameter. For example, with an insertion sleeve 30 external diameter of 14 mm, boreholes 26 with diameters of 6 to 12 mm can be provided to accommodate therein workpieces shafts which are in each case fitting or respectively of slightly smaller diameter. Here the workpieces 16 are simply inserted loosely in the boreholes 26 without further attachment or locking being urgently necessary.

In alternative embodiments, insertion sleeves 30 can be provided with boreholes of different diameters. The different diameters of the boreholes in this case are understandably to be chosen based on the respective external diameters of the insertion sleeves 30 used. An alternative design of the holder 22 can, for example, be one providing a greater number of openings 24 with a smaller diameter. For example, insertion sleeves 30 with an external diameter of 10 mm can be inserted in these openings 24, with the various insertion sleeves 30 having borehole diameters from 2 to 8 mm for example.

In general, the borehole diameters can thus be chosen based on the external diameter of the insertion sleeves and, for example, be in the range from 20 to 85% of the external diameter.

Due to their identical external dimensions, the various insertion sleeves 30 with differing borehole diameter function as adapters to arrange different workpieces 16 with differing shaft diameters on the same holder 22 of the loading device 20. Depending on the shaft length of the workpieces 16, the drill depth can also be adapted.

Each of the insertion sleeves 30 has an externally circular cylindrical shaft 32 and a head 34 with a circumferential groove 36 and a flange 38. The insertion sleeves 30 are rotationally symmetric so they can be fabricated as turned parts in a single piece. By using metal such as steel, particularly stainless steel, electric contacting of the inserted workpieces 16 can take place via the holder 22, which is also metallic.

The shape of the openings 24 is shown in FIG. 4 and FIG. 5. These comprise in each case a first, wider portion 28a and a second, narrower portion 28b. In the example shown, the portions 28a and 28b are each approximately semicircular, with the wider portion 28a with a larger diameter situated above and the narrower portion 28b with a smaller diameter below.

The spacing of the openings 24 in the two portions 28a and 28b does not run exactly perpendicular here, but instead is in each case in a slightly turned arrangement by about 15 degrees with respect to the horizontal. Here the openings 24 are situated in a counter rotated arrangement among themselves in each case, so they have an angle of rotation of about 30 degrees with respect to one another. As shown below, this serves to produce a staggered arrangement at different angles of the insertion sleeves 30 with respect to one another on the holder 22.

The insertion sleeves 30 are inserted in the holder 22 as described below with respect to FIGS. 6a to 6d. Here, the shaft 32 of a sleeve 30 is first inserted through the respective opening 24 horizontally and thus at a right angle to the upper right outer surface 44 of the holder 22 (FIG. 6b). The opening 24 and in particular its wider upper portion 28a are dimensioned so that the shaft 32 can be easily inserted through it with a little play.

The head 34 of the insertion sleeves 30 forms a retaining structure for fixating the insertion sleeve 30 on the holder 22. Here the flange 38 is dimensioned so that it cannot be inserted all the way through the opening 24 due to its larger external diameter and thus functions as a stop during insertion (FIG. 6c). In this position, the circumferential groove 36 can be brought into engagement with the edge of the opening 24, particularly the edge of the lower portion 28b.

Here the diameter of the insertion sleeve 30 is smaller than the diameter of the opening 24 in the area of the groove 36, so that it is accommodated therein with play. Consequently, the insertion sleeve 30 is not fixated in its orientation, i.e. the working angle relative to the holder 22, but instead can be tilted. As shown in FIG. 6d, after insertion the insertion sleeve 30 is tilted with respect to the horizontal by an angle of about 10 degrees, for example, so the borehole 26 is skewed slightly upward. At this working angle, the inserted workpiece 16 cannot fall out of the insertion sleeve 30.

As seen in particular in FIG. 2b, the insertion sleeves 30 assume positions which are staggered with respect to one another due to the openings 24 (FIG. 4) situated in a staggered arrangement among themselves in the direction of rotation as described above. The insertion sleeves 30 protrude from the holder 22 toward the inside and the workpieces 16 accommodated therein protrude outward from the outer surface 44 of the holder 22 with the aforementioned small working angle with respect to the horizontal. Here they do not extend in an exactly radial manner in each case, but rather point in staggered directions with respect to one another. Thus the workpieces 16 in the equipped loading device (FIG. 2a) are not parallel to one another on a holder 22, but instead have a staggered arrangement.

The insertion sleeves 30 used are locked on the holder 22 by a locking strip 40 (FIG. 2b). The locking strip 40 has a comb-like structure with a number of parallel teeth 42. The locking strip 40 is attached on the holder 22 in such a way that in each case the teeth 42 lie on the shaft 32 of the insertion sleeves 30 and lock these in the tilted position (see FIG. 6d for example). Thus the insertion sleeves 30 and the workpieces 16 inserted therein are stationary and immovably fixated with respect to the holder 22.

The coating system 10 from FIG. 1 can thus be used for coating various workpieces 16 by first of all putting together insertion sleeves 30 which fit the respective workpieces 16. The insertion sleeves 30 are then inserted in the openings 24 on the holders 22 as described and locked using the locking strip 40. With this, the loading device 20 is prepared and the workpieces 16 can be inserted. Alternatively, the insertion sleeves 30 can also be used with workpieces 16 already inserted in the openings 24.

After loading has taken place in this way, the chamber 12 can be closed and the coating process can be started. During it the rotating plate turns so the workpieces loaded outward are passed by the cathode 14 in each case such that the desired coating is deposited. After the coating has taken place, the workpieces 16 can be removed simply by pulling them out of the insertion sleeves 30.

For subsequent coating processes with the same batch size of workpieces 16 or their diameters, the loading device 20 can be used without modification. In the case of other loading, i.e. of workpieces 16 with a different diameter, individual insertion sleeves 30 or all of them can be replaced in accordance with the dimensions required.

1. A loading device for workpieces in a coating system with:
at least one stand arranged upright with an outward-facing surface in which a number of openings are arranged above one another;
and a number of insertion sleeves for accommodation in the openings, with the insertion sleeves each having a shaft and a retaining structure as well as a borehole to accommodate a workpiece;
wherein the openings and the shafts of the insertion sleeves are designed such that the insertion sleeves are insertable in the openings;
and wherein the openings (24) and retaining structures are designed such that a holding engagement results between the insertion sleeves and the openings.

2. A loading device according to claim 1, wherein
the retaining structures include a stop designed so that it cannot be inserted through the openings.

3. A loading device according to claim 1, wherein
the retaining structures have recesses on the circumference of the insertion sleeves (30) for engaging with the edges of the openings.

4. A loading device according to claim 1, wherein
the openings have a first, wider portion and a second, narrower portion,
wherein the retaining structures engage with the edge of the second portion.

5. A loading device according to claim 1, wherein
the openings and the retaining structures are designed so that the insertion sleeves are able to be guided through the openings in an insertion position perpendicular to the outer surface of the stand and the insertion sleeves in the inserted state can be tilted by a working angle with respect to the insertion position.

6. A loading device according to claim 1, wherein
the insertion sleeves are fixated in the openings with respect to the stand.

7. A loading device according to claim 1, wherein
the insertion sleeves are accommodated in the holder in such a way that the boreholes are arranged at an upward slant.

8. A loading device according to claim 1, wherein
a plurality of openings have the same shape and dimension.

9. A loading device according to claim 1, wherein
there are openings on the stand arranged in a staggered and/or skewed manner with respect to one another.

10. A loading device according to claim 1, wherein
an arrangement of openings (24) above one another on the stand is formed such that with the existing engagement with the insertion sleeves accommodated therein these are arranged with at least two different angles with respect to the stand.

11. A loading device according to claim 1, wherein
the stand is made as a sheet metal part and the insertion sleeves are made as turned parts.

12. A loading device according to claim 1, wherein
a device is provided for rotating the stand about a vertically situated axis of rotation (A).

13. A coating system with:
a coating chamber;
a loading device according to one of the preceding claims inside the coating chamber; and
coating agents for applying a coating to the workpieces held in the loading device.

14. A coating system according to claim 13, wherein
the coating chamber is designed as a vacuum chamber,
and the coating agents are designed to produce a plasma.

15. A method for loading workpieces in a coating system, wherein
workpieces are inserted in boreholes of insertion sleeves, with the insertion sleeves each having a shaft and a retaining structure,
and the insertion sleeves are inserted in openings arranged above one another in an outward-facing surface of at least one stand which is arranged upright by inserting the shafts (32) through the openings,
wherein a holding engagement is formed between the retaining structures of the insertion sleeves and the openings.
